(19) United States
(12) Patent Application Publication
(10) Pub. No.: US 2010/0141820 A1
(43) Pub. Date: Jun. 10, 2010

(54) IMAGE SENSOR HAVING CUT-OFF CORNERS, WITH A MULTIPLEXER BETWEEN TWO ADJACENT ROWS OF PIXELS

(75) Inventors: Gregoire Chenebaux, Grenoble (FR); Thierry Ligozat, Grenoble (FR)

Correspondence Address: LOWE HAUPTMAN HAM & BERNER, LLP, 1700 DIAGONAL ROAD, SUITE 300, ALEXANDRIA, VA, 22314, US

(73) Assignee: E2V Semiconductors, Saint Egreve (FR)

(21) Appl. No.: 12/518,757

(22) PCT Filed: Apr. 29, 2009
(86) PCT No.: PCT/EP2009/055225

§ 371 Date: Jun. 22, 2009

(30) Foreign Application Priority Data
Apr. 30, 2008 (FR) 08/02417

(51) Int. Cl. H04N 5/335

(52) U.S. Cl. 348/302; 348/E05.092

(57) ABSTRACT

The invention relates to matrix image sensors. It applies most particularly to intraoral dental radiology sensors. The invention provides a sensor architecture comprising a column decoder controlling select conductors of a column, and a row decoder controlling select conductors of a row. The pixels of a column are connected to a signal conductor that extends along the column and goes toward an analog multiplexer extending within the pixel matrix between two rows of pixels of the matrix. The multiplexer is controlled via the column select conductors coming from the decoder and it transmits the signal from a signal conductor of a selected column to an output conductor extending parallel to the rows. A signal sampling circuit common to all the columns is connected at the end of the output conductor of the multiplexer. An increase in matrix area is achieved by in practice losing only a single image row.

### CROSS-REFERENCE TO RELATED APPLICATIONS

The present Application is based on International Application No. PCT/EP2009/055225, filed on Apr. 29, 2009, which in turn corresponds to French Application No. 0802417 filed on Apr. 30, 2008, and priority is hereby claimed under 35 USC §119 based on these applications. Each of these applications are hereby incorporated by reference in their entirety into the present application.

### FIELD OF THE INVENTION

The invention relates to matrix image sensors. It applies most particularly, but not exclusively, to intraoral dental radiology sensors, the sensor then being covered with a scintillator that converts X-rays into visible light, the invention being described in this particular case.

### BACKGROUND OF THE INVENTION

In the application of intraoral dental radiology, it is important to have both a sensor shape sufficiently comfortable for the patient and an image acquisition matrix as large as possible relative to the overall size of the sensor.

Sensors initially of rectangular shape were very uncomfortable for the gums. It has therefore been proposed to use sensors having a rectangular shape with cut-off corners. FIG. 1 shows several sensor shapes: in FIG. 1A, in a top view, a conventional rectangular shape; the cable connecting the sensor to the outside of the mouth is visible; in FIG. 1B the same sensor in side view; in FIG. 1C a rectangular sensor having two cut-off corners in a top view and in FIG. 1D a rectangular sensor having four cut-off corners, which is the most comfortable shape.

The overall dimensions of such sensors are about 20 mm in width, 30 mm in length. The corners may for example be cut off to 5 mm in length and 5 mm in width (45° cut-off).

However, if it is desirable for the pixel matrix that captures the image to have the largest possible area, it is necessary for the matrix itself to have cut-off corners. This complicates the architecture of the sensor, whether this be produced in CCD technology or in MOS technology.

In the case of CCD sensors having a pixel matrix with cut-off corners, it is difficult to position the charge transfer registers and read-out registers necessary for reading the charges generated in each pixel by the illumination. In the case of MOS sensors having a matrix with cut-off corners, it is also difficult to position the read-out circuits at the bottom of the columns of the matrix without increasing the length of the integrated-circuit chip.

It will be recalled that the standard architecture of a matrix image sensor in MOS technology is in general the following: the rows of pixels are oriented along the width direction of the chip; the columns are oriented along the length direction; the read-out (signal sampling) circuits are located at the bottom of the matrix and comprise at least one sampling circuit at the foot of each column; a multiplexer is placed beneath the read-out circuits for delivering in succession, to a common output of the chip, signals corresponding to each pixel; a row decoder is placed on a lateral side of the matrix, for addressing the rows in succession, and a column decoder is placed beneath a lower edge of the matrix, for controlling the multiplexer; an analog-digital converter may be provided at the foot of each column, the multiplexer then being placed downstream of the converters, or an overall analog-digital converter is provided for all the columns, the multiplexer being placed upstream of the converter; and finally, the pads needed for connecting the chip to the outside are also placed at the bottom of the matrix.

When the corners of the matrix are cut off, it is difficult to find space for all these circuits between the bottom of the matrix and the bottom of the integrated-circuit chip, and it is necessary to lengthen the chip.

It has already been proposed to place the row decoders on the one hand and the column decoders with the read-out and multiplexing circuits on the other hand in the middle of the matrix rather than along the edges, but the decoders and read-out circuits are bulky. If the row decoder is placed between two columns, only a very small number of columns may probably be lost, perhaps just a single column, which may be reconstituted by interpolation of the adjacent columns. However, if the column decoder and its read-out and multiplexing circuits are placed between two rows, then a lot more columns are lost, which is in general not acceptable. It is indeed the column decoder and the read-out circuits that occupy a large amount of space at the bottom of the matrix.

### SUMMARY OF THE INVENTION

The present invention starts from this observation, so as to provide a different sensor architecture which may require in principle modifying the elementary structure of a pixel, but which makes it possible to save a great deal of space at the bottom of the matrix, by minimizing the size of the circuits necessary for collecting the signals coming from the columns.

The invention provides an image sensor comprising a pixel matrix organized in rows and columns, a column decoder controlling column select conductors extending along the columns, a row decoder controlling row select conductors extending along the rows, and a respective signal conductor along each column, the pixels of a given column having their outputs connected to this signal conductor, characterized in that it comprises:

an analog multiplexer extending within the pixel matrix between two rows of pixels of the matrix, the multiplexer comprising an output conductor extending parallel to the rows and having, for each column, a respective signal input connected to the signal conductor of the column, and a control input connected to the column select conductor; and

a signal sampling circuit common to all the columns, this circuit having an input connected to the output conductor of the multiplexer.

Using a sampling circuit common to all the columns, it is unnecessary to place sampling circuits between two rows of the matrix, which would occupy too much space, and, moreover, the size of the read-out circuits outside the matrix is minimized.

If the sampling circuit must operate in double-sampling mode, in which two measurement samples are taken, namely a first sample before pixel resetting and a second sample after pixel resetting, a pixel has to be able to be precisely reset without resetting the other pixels. In conventional architectures, the pixels may be reset using a signal sent onto a row conductor, it being possible for all the pixels of a given row to be able to be reset at the same time, said pixels being read out in parallel. Here, a pixel has to be reset immediately after it has been read out and before the pixel of a following column is read out.

Consequently, each pixel is preferably provided with a pixel reset circuit controlled both:

by a reset conductor specific to each row and connected to a corresponding output of the row decoder; and

by a column conductor connected to a corresponding output of the column decoder.

The row conductor is preferably a second row conductor. The column conductor may be the column select conductor that controls the multiplexer. The column select conductor is then connected not only to a control input of a multiplexer but also to all the pixels of the column, which is not the usual practice in conventional MOS sensors.

The pixel reset circuit, in the case of a pixel having a photodiode as photosensitive element, will preferably consist of two series-connected transistors between a positive reference voltage and the cathode of the photodiode, one of the transistors being driven via the second row conductor and the other transistor via the column select conductor.

The column decoder may be placed along a lateral edge of the matrix or divided between the two lateral edges. The row decoder may be placed at the bottom of the matrix or divided between the bottom and the top of the matrix.

Preferably, the multiplexer is entirely housed in a space having a width at most equal to the inter-row spacing of the matrix.

It comprises, for each column, a switch connecting the signal conductor of the column to the output conductor of the multiplexer, this switch being controlled by the column select conductor.

Preferably, a current source is associated with each column, said source being housed in the same space of width less than or equal to the spacing of the rows and connected to the signal conductor of the column in question.

The multiplexer may comprise, for each column, a buffer amplifier (preferably a simple follower transistor or a differential pair of transistors, configured as a unitary gain amplifier) between the signal conductor and the switch that are associated with this column.

In a variant, the current source is common to all the columns and is connected to the output conductor of the multiplexer. It is therefore placed at the bottom of the matrix and not in the space reserved for the multiplexer. In this case, there is no buffer amplifier between the signal conductor of the column and the switch of the multiplexer.

The structure of an individual pixel of the sensor may be a simple structure, in which the charges generated by the light are stored on the photodiode and then read out from the photodiode, or a more complex structure (requiring one more transistor) comprising an intermediate storage node, the charges being stored on the photodiode during illumination, then transferred into the intermediate storage node before being read out from the intermediate storage node. In the latter case, the abovementioned reset circuit is the circuit for resetting the intermediate node, i.e. the two series-connected transistors for the resetting are connected between the intermediate storage node and a positive reference potential.

One particularly advantageous application of the invention is, as already mentioned, an intraoral dental radiology sensor having an integrated-circuit chip with cut-off corners (preferably four cut-off corners), the pixel matrix of which has itself cut-off corners like those of the chip.

In this application, it is desirable for the column decoder and the row decoder to be capable, at the start of image acquisition, of selecting all the columns at once and all the rows at once (at the very least the second row conductor, the one serving for resetting) in order to carry out overall resetting of all the pixels at a given instant, which is the start of an X-ray flash.

Preferably, the radiology sensor comprises a rectangular chip, and the multiplexer is then lengthened along the direction of the longest dimension (length) of the rectangle whereas the signal conductors parallel to the columns are oriented along the direction of the shortest dimention (width) of the rectangle. However, it is also conceivable to have an arrangement in which the multiplexer is oriented along the direction of the shortest dimension and the column conductors are oriented along the direction of the longest dimension.

It should be noted that the invention is compatible with reading out only part of the matrix, since any pixel is accessible by addressing the row and the column at the intersection of which the pixel lies. It is therefore unnecessary for all the rows of the matrix to be read out in succession, or for all the pixels of an addressed row to be read out in succession.

Still other objects and advantages of the present invention will become readily apparent to those skilled in the art from the following detailed description, wherein the preferred embodiments of the invention are shown and described, simply by way of illustration of the best mode contemplated of carrying out the invention. As will be realized, the invention is capable of other and different embodiments, and its several details are capable of modifications in various obvious aspects, all without departing from the invention. Accordingly, the drawings and description thereof are to be regarded as illustrative in nature, and not as restrictive.

### BRIEF DESCRIPTION OF THE DRAWINGS

The present invention is illustrated by way of example, and not by limitation, in the figures of the accompanying drawings, wherein elements having the same reference numeral designations represent like elements throughout and wherein:

FIG. 1 shows the general appearance of dental radiology sensors;

FIG. 2 shows the overall architecture of the sensor according to the invention;

FIG. 3 shows an individual pixel structure adapted to the architecture according to the invention;

FIG. 4 shows the pixel matrix, the multiplexer and the read-out circuit connected to the output of the multiplexer; and

FIG. 5 shows the control signals that may be used for operating the pixel matrix.

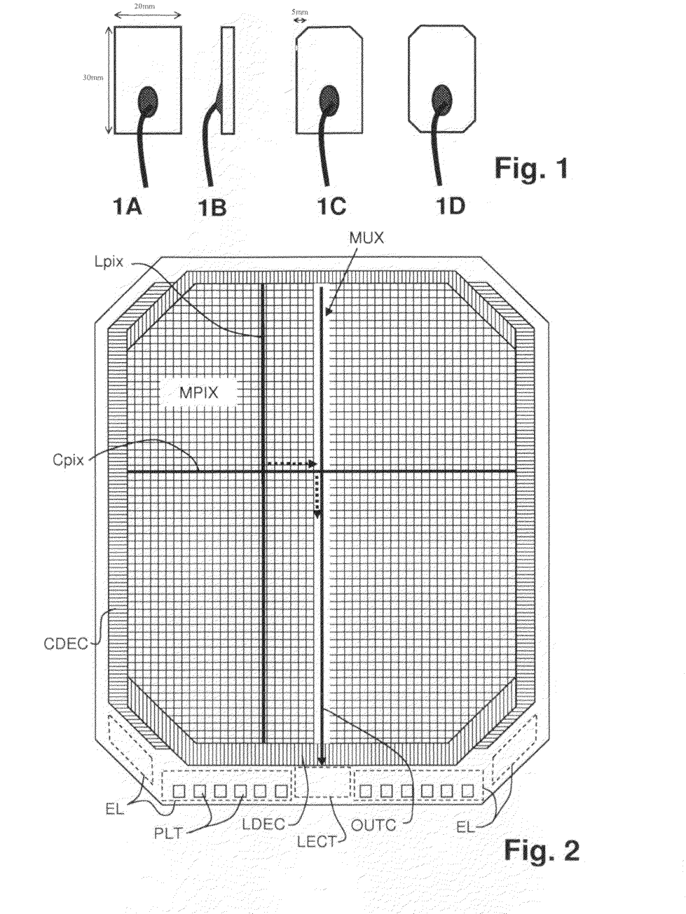

### DETAILED DESCRIPTION OF THE INVENTION

FIG. 2 shows the general structure of the image sensor according to the invention, for an intraoral dental radiology sensor formed on a rectangular integrated-circuit chip with four cut-off corners. The chip measures for example about 20 millimeters in width by 30 millimeters in length, and the corners are cut off to a width and a length of about 5 millimeters. These numerical values are given by way of realistic examples.

The pixel matrix is denoted by MPIX. It covers as large an area of the chip as possible. The areas not occupied by the pixel matrix are those needed for housing the row decoder LDEC and the column decoder CDEC, the various electronic circuits EL and notably the read-out electronics LECT for getting the image information generated in the pixels, and finally the pads PLT for connection to the outside of the chip.

In order for the available space on the chip with cut-off corners to be optimally filled by the pixel matrix MPIX, the matrix itself is also provided with cut-off corners. The row decoder LDEC (vertically hatched area) extends over the entire width of the matrix MPIX at the bottom thereof while the column decoder CDEC (horizontally hatched area) extends over the entire length of the matrix MPIX, along one side thereof. However, it is also conceivable for the row decoder to be duplicated and be present both at the top and at the bottom of the matrix, each decoder half addressing every other row of the matrix. Likewise, the column decoder may also be duplicated, being present both on the left and the right of the matrix, each part of the decoder addressing every other column.

The notion of rows and columns is a conventional functional notion. To define the notion of a row as opposed to the notion of a column, it will be considered that the row decoder serves for selectively addressing a predetermined row of pixels from among all the rows of the matrix, so as to connect all the pixels of this row to respective column conductors which connect all the pixels of a given column and are used to collect a useful signal coming from the pixel. The pixels of the row addressed at a given moment are in principle read out in succession as the output of the matrix. The column decoders are used to select a pixel from the addressed row. When the pixels of an addressed row have all been read out in succession, the row decoder addresses another row.

In the application to an intraoral dental radiology sensor, it is preferable for the output connections (connection pads) to be placed at one end of the longest dimension (length) of the chip and this is the solution shown in FIG. 2. In this case, the architecture according to the invention lends itself better to the rows of pixels being oriented along the length direction of the integrated circuit, the columns of pixels being along the width direction, whereas the reverse approach is generally preferred in conventional MOS sensor architectures.

In FIG. 2, a row of pixels Lpix along the length direction and a column of pixels Cpix along the width direction are indicated as bold lines.

The principle of the architecture according to the invention is the following:

an analog multiplexer MUX is placed in a reserved area extending between two adjacent rows of pixels of the matrix MPIX, preferably in the part where the matrix is longest, i.e. away from the area having cut-off corners. This multiplexer comprises one respective signal input per column, one respective control input per column and an output in the form of a conductor OUTC, which extends parallel to the rows and goes to read-out circuits LECT located outside the matrix, at the bottom thereof;

the rows of pixels are each controlled via a respective row select conductor, which connects all the pixels of a given row. These row conductors are controlled by the row decoder LDEC. The latter produces a row select signal that activates a predetermined row select conductor in order to select the pixels of a predetermined row of the matrix. The pixels thus selected are each connected to a column conductor associated with the column to which the pixel belongs;

a first and a second column conductor connecting all the pixels of a given column are associated respectively with each column of pixels. The first column conductor is a signal conductor which connects the outputs of all the pixels of the column to a signal input (associated with this column) of the multiplexer MUX. The second column conductor is a control conductor of the multiplexer, which is connected to the multiplexer control input associated with this column: when a column select signal is sent to this conductor via the column decoder, it is the multiplexer input corresponding to this column that is selected and it is then the signal present on the first conductor, or signal conductor, of the same column which is transmitted to the output conductor OUTC; and

the read-out of the signal thus multiplexed, and notably the sampling for the purpose of analog-digital conversion, is performed outside the matrix.

Thus, the signal generated by a pixel at the intersection of a predetermined row and a predetermined column will be read out when the row decoder selects this row and only if the column decoder permits a signal to pass between this column and the output conductor.

The width of the multiplexer is preferably equal to or less than the width of a row of pixels, so that a single image row is lost because of the presence of this multiplexer.

The column decoder is on the side of the matrix while the row decoder is at the bottom of the matrix. However, the column decoder may be divided into two parts located on the left-hand side and right-hand side of the pixel matrix respectively (as may be seen in FIG. 2), but this arrangement is optional. Likewise, the row decoder may optionally be divided into two parts located at the top and bottom of the matrix respectively.

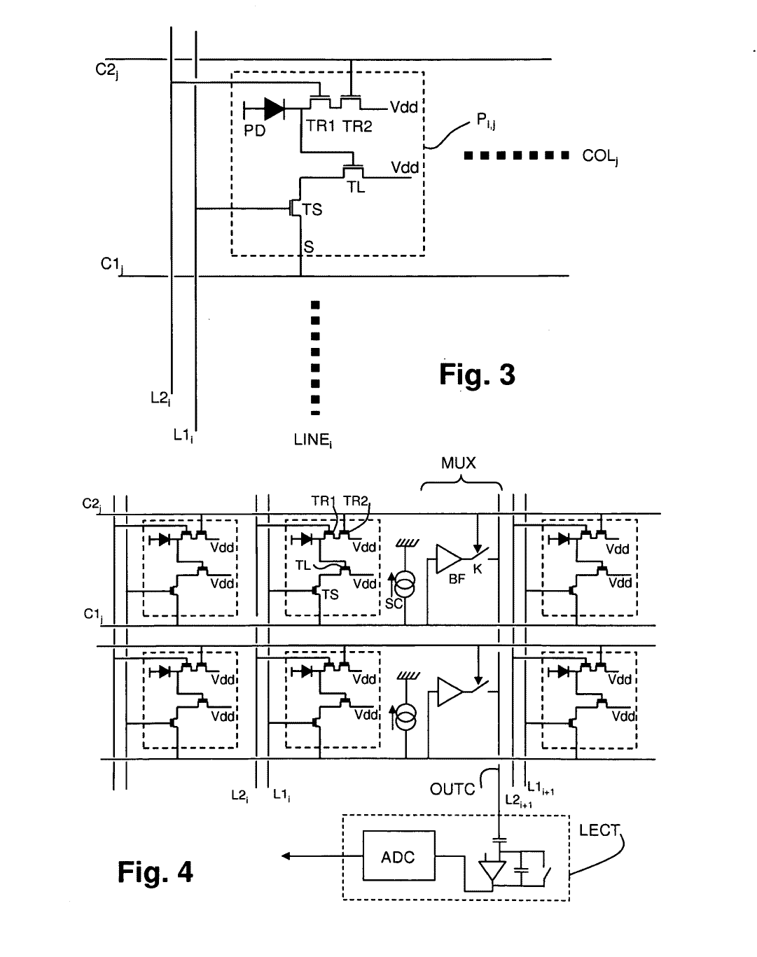

It will now be shown, with reference to FIG. 3, how this architecture may be implemented for a matrix in which each pixel comprises a photodiode, a reset circuit, a row select transistor and a follower transistor.

FIG. 3 shows the structure of such an individual pixel suitable for implementing the invention.

The pixel P_{i,j}, at the intersection of the row LINEᵢ of index i and the column COLⱼ of index j, comprises a photodiode PD having its anode at a common ground and its cathode connected to a reset circuit controlled both via a row conductor and via a column conductor. This reset circuit controlled both row-wise and column-wise is necessary if it is desired to read out the signal at the bottom of the matrix by correlated double sampling.

The reset circuit serves to apply a reset voltage (for example the overall supply voltage Vdd or another sufficiently positive reference voltage) to the photodiode if and only if a reset command is given via a row conductor and a column conductor. The reset command is given after a charge integration cycle.

In its simplest version, the reset circuit simply comprises two series-connected transistors TR1 and TR2 which connect the photodiode to the reference voltage, as will be explained later. Both must be in the on-state to authorize this resetting. A logic gate could also be used, but the solution with two transistors connected in series is the simplest.

The cathode of the photodiode is connected to the gate of a read-out transistor TL, which has its drain connected to the supply voltage Vdd and has its source connected via a row select transistor TS to an output S of the pixel. The output S of the pixel is connected to a signal conductor associated with the column COLⱼ, this signal conductor being a first column conductor C1ⱼ extending parallel to the column. All the outputs S of the pixels of the column are connected to this first column conductor.

The row select transistor TS has its gate controlled via a first row conductor L1ᵢ, which will be called the row select conductor, associated with the row LINEᵢ. All the transistors TS of the pixels of the row LINEᵢ are thus connected to the conductor L1ᵢ, which is connected to a respective output of the row decoder. When this conductor is active, a signal output by the photodiode may be transmitted to the signal conductor C1ⱼ associated with the column. Otherwise, the pixel remains isolated from the conductor C1ⱼ. The row decoder ensures that only a single row at a time is thus activated for reading out the photogenerated charges.

Resetting of the photodiode after reading out a pixel serves for two purposes: firstly, for placing the charge storage area at a high reference potential which progressively decreases upon illumination of the photodiode, in proportion to this illumination, and, secondly, for allowing the charges to be measured by double sampling. The signal output by the pixel is measured at the end of an integration cycle and just after resetting, so as to tell the difference between the two measurements, this difference actually representing the charges due to the illumination. Of course, the photodiode would be reset by a low potential if the photodiode stored holes rather than electrons.

For this purpose, the transistor TR1 is connected to a second row conductor L2ᵢ, or reset conductor, associated with the row LINEᵢ. The other transistor TR2 is connected to a second column conductor C2ⱼ which is the column select conductor connected to a respective output of the column decoder CDEC; it is this column select conductor that controls the multiplexer MUX in order to transmit the signal present on the signal conductor C1ⱼ to the output OUTC of this multiplexer. All the transistors TR1 of the pixels of the row LINEᵢ have their gate controlled via the reset conductor L2ᵢ. All the transistors TR2 of the pixels of the column COLⱼ have their gate connected to the column select conductor C2ⱼ.

Other embodiments are possible, in which the transistor TR1 is not necessarily controlled via a row conductor.

Thus, the sensor architecture according to the invention requires (if double sampling is desired) that the resetting of the photodiode be placed under the control of the row decoder and that of the column decoder. In the architectures of the prior art, only the row decoder is used to control the resetting, and the pixel comprises only one transistor TR1 or TR2 controlled via the second row conductor, and not both transistors.

FIG. 4 shows in greater detail a preferred embodiment of the sensor architecture in the case of use of the pixel of FIG. 3. Shown horizontally are two columns of pixels and shown vertically are three rows, two adjacent rows of which are separated by a space reserved for the multiplexer MUX. The pixels are in accordance with the pixels of FIG. 3.

Placed in the space reserved for the multiplexer and facing each column is a current source SC that does not form part of the multiplexer but serves to drain a current (which is the same for all the columns to within the technological dispersions) from the respective signal conductor of each column. This current source enables the follower transistor TL of the pixel currently activated by a row conductor L1ᵢ to behave effectively in the follower mode (the follower transistors of the pixels that are not activated have a high-impedance output, isolated by the transistor TS). Here, the current source is connected between the signal conductor C1ⱼ and a common ground.

The multiplexer MUX comprises, for each column of pixels, an elementary multiplexing circuit which is identical for all the columns and possesses (in the case of the pixel P_{i,j}):

a signal input connected to the signal conductor C1ⱼ which, as will be recalled, is itself connected to the outputs of all the pixels of the column;

a buffer amplifier BF connected to this signal input, if it is desired to avoid charging the pixel directly via the capacitors of the read-out circuit LECT. This amplifier may be a simple follower transistor or a differential pair configured as a unitary gain amplifier; and

a control input and a switch K controlled via this input. The control input is connected to the column select conductor C2ⱼ, while this switch connects the output of the buffer amplifier BF to the output conductor OUTC of the multiplexer if and only if the column is designated by the column decoder.

The multiplexer therefore selects a column, upon control of a column select conductor C2ⱼ designated by the column decoder, in order to connect the corresponding signal conductor C1ⱼ to the conductor OUTC, the other signal conductors of the other columns being isolated. An output signal from a single pixel, designated by the row decoder, is present on this signal conductor.

The output conductor OUTC is connected to the input of a read-out circuit LECT. The read-out circuit is represented symbolically by a multi-capacitor sampler and an analog-digital converter ADC. Its function is to sample the analog voltage present on the conductor OUTC and convert it to a digital signal.

In practice, the read-out circuit is designed to perform double sampling so as to firstly read out the output signal from the pixel after an integration cycle for integrating the charges due to the light, then the output signal after the photodiode PD of this pixel has been reset. The signal, which is converted into a digital signal, is the difference between these two successive read-outs. Double sampling circuits are well known and, in conventional sensor architectures in MOS technology, there is a double sampling circuit at the bottom of each column of pixels. Here, there is only a single sampling circuit for the entire matrix, placed at the bottom of the output conductor OUTC.

The operation of the circuit of FIG. 4 for a charge integration cycle is the following:

a) the rows of pixels are read out one after another. The row decoder selects a row via its first row conductor L1ᵢ which connects the follower transistors TL of the pixels of this row to the respective signal conductors and supplies them with current. The first column conductor or signal conductor associated with the column then assumes a potential level that corresponds (to within offset) to the voltage level present on the photodiode;

b) the columns are selected in succession by the column decoder while a row is being addressed. When the column of index j is selected, the switch K corresponding to this column is closed and connects the signal conductor C1ⱼ to the output OUTC. The signal from the pixel is sampled (first sampling). While the column of index j remains selected by the column decoder, the transistor TR2 is in the on-state but the transistor TR1 is in the off-state during this first sampling;

c) a short pulse for resetting the photodiode is then sent by the row decoder to the reset conductor L2ᵢ of the row currently selected. This pulse turns the transistor TR1 on. The two transistors TR1 and TR2 are therefore simultaneously in the on-state, thereby resetting the photodiode of the pixel in question. The pixels of the other rows are not reset (the transistor TR1 is in the off-state) and the pixels of the other columns are not reset (the transistor TR2 is in the off-state). A second sampling is then performed by the read-out circuit LECT. The difference between the two sampled levels is converted into a digital signal by the analog-digital converter ADC and actually represents the quantity of charge due to the illumination from the start of the sampling cycle (the start of the cycle is defined by the end of the reset pulse sent to the reset conductor L2ᵢ);

d) the next column is selected and operations b and c are repeated for each column;

e) the next row is selected when all the columns have been read out in succession. Operations a, b, c and d are repeated for each row, including both the rows located on the left-hand side of the multiplexer and those located on the right-hand side of the multiplexer, it being noted that, depending on the index of the row addressed, the number of columns read out in succession will not always be the same: constant number for rows at the center of the matrix, but decreasing number for the rows that terminate on cut-off corners of the matrix.

Note that it is possible to decide to read out only certain areas of the sensor (a region of specific interest, or even a single pixel) if so desired. It is sufficient to limit the row and column addressing to the chosen areas.

Although the preferred solution consisting in selecting a row and then reading out, column by column, all the pixels of the row, has been described above, it would also be possible to select a column and read out, row by row, all the pixels of the column before selecting another column.

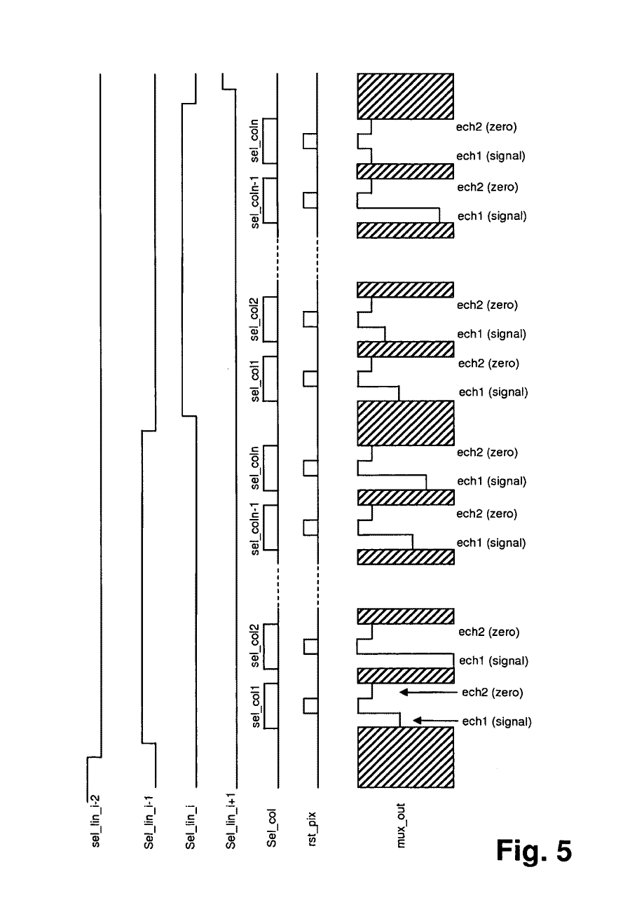

The timing diagram of FIG. 5 summarizes the principle of the read-out.

The signals sel_lin_i-2, sel_lin_i-1, and sel_lin_i represent respectively the signals applied by the row decoder LDEC in succession to the first row conductors of index i-2, i-1 and i respectively.

The timing diagram for the row sel_col represents the instants when an active level is applied by the column decoder CDEC to a column select conductor so as to select a column to be read out. The active level acts so as to connect the first column conductor to the output of the multiplexer. The active levels are applied in succession to the various columns of index j (from 1 to n) while each of the rows is being addressed.

The square pulses rst_pix represent the instants at which a reset pulse is applied to a pixel. The pulse is applied to the second row conductor L2ᵢ and is applied only to the row during addressing, but is applied as many times as there are columns read out while the row is being addressed.

The signal mux_out is that which appears on the output conductor OUTC of the multiplexer. The level is indeterminate (high impedance) outside the instants when a column is addressed by the signal sel_col. While the column is being addressed, it assumes a first value before the pulse rst_pix and a second value after this pulse. The first value represents the voltage level of the photodiode after an illumination cycle. The second level represents the voltage reference of the photodiode after resetting.

A first sampling ech1 is performed before the pulse rst_pix and a second sampling ech2 is performed after this pulse, for each column selected. It is the difference between the two sampled levels that is converted by the analog-digital converter ADC.

An arrangement in which the photodiode reset conductor is a conductor L2ᵢ extending parallel to a row of pixels, this conductor then being connected to the row decoder, has mainly been described above. However, a different arrangement may be provided, in which:

the conductor L1ᵢ controls both the select transistor TS and the transistor TR1; and

an additional conductor C3ⱼ parallel to the column controls the switch K corresponding to the selected column of pixels, the conductor C2ⱼ controlling only the transistor TR2.

In this different configuration, the resetting is controlled by the column decoder and not by the row decoder.

To simplify matters, it has been considered that the multiplexer had a single output OUTC going toward the bottom of the matrix. It will be understood that the output may be a differential output, in which case there may be two conductors OUTC. Moreover, it is conceivable for the read-out circuits LECT to be duplicated and be present both at the top and the bottom of the matrix. In the latter case, provision may be made for half of the columns to exit around the bottom of the matrix and the other half to exit around the top.

Hitherto, a pixel has been considered with its base structure comprising, at the intersection of a row and a column, a photodiode (PD), a follower transistor (TL), the gate of which is connected to the photodiode, and a row select transistor (TS) connected between the follower transistor and the signal conductor of the column in question.

The invention is also applicable to other types of pixels, and notably a pixel comprising a photodiode, a transfer transistor connected between the photodiode and an intermediate storage node, a follower transistor, the gate of which is connected to the intermediate storage node, and a row select transistor connected between the follower transistor and the signal conductor of the column in question, the row select transistor having its gate connected to the row select conductor of the row in question. The reset circuit is connected to the storage node (and not to the photodiode) in order to establish a reference potential on the latter. It should be noted in this case that the double sampling circuit, which establishes a difference between a pre-reset signal sample and a post-reset signal sample, operates as follows: the storage node is reset; the first charge sample on the reset node is read out; the charges on the photodiode are transferred to the storage node immediately after this resetting; and finally the second sample is read out. The difference between the two samples is measured.

It will be readily seen by one of ordinary skill in the art that the present invention fulfils all of the objects set forth above. After reading the foregoing specification, one of ordinary skill in the art will be able to affect various changes, substitutions of equivalents and various aspects of the invention as broadly disclosed herein. It is therefore intended that the protection granted hereon be limited only by definition contained in the appended claims and equivalents thereof.

1. An image sensor comprising a pixel matrix organized in rows and columns, a column decoder controlling column select conductors extending along the columns, a row decoder controlling row select conductors extending along the rows, and a respective signal conductor along each column, the pixels of a given column having their outputs connected to this signal conductor, said image sensor further comprising:
an analog multiplexer extending within the pixel matrix between two rows of pixels of the matrix, the multiplexer comprising an output conductor extending parallel to the rows and having, for each column, a respective signal input connected to the signal conductor of the column, and a control input connected to the column select conductor; and
a signal sampling circuit common to all the columns, this circuit having an input connected to the output conductor of the multiplexer.

2. The sensor as claimed in claim 1, wherein the multiplexer is entirely housed in a space having a width at most equal to the inter-row spacing of the matrix.

3. The sensor as claimed in claim 1, comprising, for each column, a switch connecting the signal conductor of the column to the output conductor of the multiplexer, this switch being controlled by the column select conductor.

4. The sensor as claimed in claim 1, wherein a respective current source for each column, which is identical for all the columns, is connected to the signal conductor of the column in question.

5. The sensor as claimed in claim 1, wherein the multiplexer comprises, for each column, a buffer amplifier between the signal conductor associated with this column and the switch.

6. The sensor as claimed in claim 1, wherein it includes a current source connected to the output conductor of the multiplexer.

7. The sensor as claimed in claim 1, wherein each pixel comprises a reset circuit controlled both by the column select conductor and by a reset conductor extending parallel to the row of which the pixel forms part, this reset conductor being controlled by the row decoder so as to authorize pixel resetting only if the column select conductor and the reset conductor are activated by the column and row decoders respectively.

8. The sensor as claimed in claim 7, wherein the pixel reset circuit comprises two series-connected transistors, one having its gate connected to the reset conductor and the other having its gate connected to the column select conductor.

9. The sensor as claimed in claims 7, wherein the sampling circuit is a double sampling circuit for establishing a difference between a pre-reset signal sample and a post-reset signal sample.

10. The sensor as claimed in claim 7, wherein the pixel at the intersection of a row and a column comprises a photodiode, a follower transistor, the gate of which is connected to the photodiode, and a row select transistor connected between the follower transistor and the signal conductor of the column in question, the row select transistor having its gate connected to the row select conductor of the row in question, the reset circuit being connected to the photodiode in order to establish a reference potential on the latter.

11. The sensor as claimed in claim 7, wherein the pixel at the intersection of a row and a column comprises a photodiode, a transfer transistor connected between the photodiode and an intermediate storage node, a follower transistor, the gate of which is connected to the intermediate storage node, and a row select transistor connected between the follower transistor and the signal conductor of the column in question, the row select transistor having its gate connected to the row select conductor of the row in question, the reset circuit being connected to the storage node in order to establish a reference potential on the latter.

12. The sensor as claimed in claim 1, covered with a scintillator, which is formed on a rectangular integrated-circuit chip having cut-off corners.

13. The sensor as claimed in claim 12, wherein the multiplexer extends along the direction of the longest dimension of the rectangular chip, and the signal conductors extend along the direction of the shortest dimension of the chip.

14. The sensor as claimed in claim 2, comprising, for each column, a switch connecting the signal conductor of the column to the output conductor of the multiplexer, this switch being controlled by the column select conductor.

15. The sensor as claimed in claims 8, wherein the sampling circuit is a double sampling circuit for establishing a difference between a pre-reset signal sample and a post-reset signal sample.

16. The sensor as claimed in claim 8, wherein the pixel at the intersection of a row and a column comprises a photodiode, a follower transistor, the gate of which is connected to the photodiode, and a row select transistor connected between the follower transistor and the signal conductor of the column in question, the row select transistor having its gate connected to the row select conductor of the row in question, the reset circuit being connected to the photodiode in order to establish a reference potential on the latter.

17. The sensor as claimed in claim 9, wherein the pixel at the intersection of a row and a column comprises a photodiode, a follower transistor, the gate of which is connected to the photodiode, and a row select transistor connected between the follower transistor and the signal conductor of the column in question, the row select transistor having its gate connected to the row select conductor of the row in question, the reset circuit being connected to the photodiode in order to establish a reference potential on the latter.

18. The sensor as claimed in claim 8, wherein the pixel at the intersection of a row and a column comprises a photodiode, a transfer transistor connected between the photodiode and an intermediate storage node, a follower transistor, the gate of which is connected to the intermediate storage node, and a row select transistor connected between the follower transistor and the signal conductor of the column in question, the row select transistor having its gate connected to the row select conductor of the row in question, the reset circuit being connected to the storage node in order to establish a reference potential on the latter.

19. The sensor as claimed in claim 9, wherein the pixel at the intersection of a row and a column comprises a photodiode, a transfer transistor connected between the photodiode and an intermediate storage node, a follower transistor, the gate of which is connected to the intermediate storage node, and a row select transistor connected between the follower transistor and the signal conductor of the column in question, the row select transistor having its gate connected to the row select conductor of the row in question, the reset circuit being connected to the storage node in order to establish a reference potential on the latter.

20. The sensor as claimed in claim 2, covered with a scintillator, which is formed on a rectangular integrated-circuit chip having cut-off corners.
